(19) United States
(12) Patent Application Publication
(10) Pub. No.: US 2024/0043993 A1
(43) Pub. Date: Feb. 8, 2024

(54) SUBSTRATE PROCESSING APPARATUS, METHOD OF PROCESSING SUBSTRATE, METHOD OF MANUFACTURING SEMICONDUCTOR DEVICE, CLEANING METHOD, AND RECORDING MEDIUM

(71) Applicant: Kokusai Electric Corporation, Tokyo (JP)

(72) Inventor: Naonori AKAE, Tokyo (JP)

(73) Assignee: Kokusai Electric Corporation, Tokyo (JP)

(21) Appl. No.: 18/341,239

(22) Filed: Jun. 26, 2023

(30) Foreign Application Priority Data
Aug. 4, 2022 (JP) 2022-124636

(51) Int. Cl. C23C 16/44; H01J 37/32; H01L 21/02

(52) U.S. Cl. CPC C23C 16/4405; H01J 37/32862; H01J 37/32449; H01L 21/0217; H01L 21/02274; H01L 21/0228; H01J 37/32357

(57) ABSTRACT

There is provided a technique that includes: a process chamber capable of processing a substrate; a substrate mounting table including a substrate mounting surface; a process gas supply system supplying process gas into the process chamber; a cleaning gas supply system supplying cleaning gas and cleaning assistant gas to a side surface of the substrate mounting table; an exhaust system capable of exhausting an atmosphere in the process chamber; and a controller capable of controlling the process gas supply system, the cleaning gas supply system, and the exhaust system such that the process gas is supplied to the process chamber while the substrate is on the substrate mounting surface and the cleaning gas and the cleaning assistant gas are supplied to the side surface of the substrate mounting table while the substrate is not on the substrate mounting surface.

### CROSS-REFERENCE TO RELATED APPLICATION

This application is based upon and claims the benefit of priority from Japanese Patent Application No. 2022-124636, filed on Aug. 4, 2022, the entire contents of which are incorporated herein by reference.

### TECHNICAL FIELD

The present disclosure relates to a substrate processing apparatus, a method of processing a substrate, a method of manufacturing a semiconductor device, a cleaning method, and a recording medium.

### BACKGROUND

In the related art, there is a substrate processing apparatus used in a process of a method of manufacturing a semiconductor device, which is configured to process a substrate by supplying a process gas to a process chamber while the substrate is placed on a substrate mounting table installed in the process chamber.

An unintended film may be formed on a substrate mounting table. The unintended film may affect a substrate processing.

### SUMMARY

The present disclosure provides a technique capable of reducing an influence of an unintended film formed on a substrate mounting table.

According to some embodiments of the present disclosure, there is provided a technique that includes: a process chamber configured to be capable of processing a substrate; a substrate mounting table including a substrate mounting surface on which the substrate is placed; a process gas supply system configured to supply a process gas into the process chamber; a cleaning gas supply system configured to supply a cleaning gas and a cleaning assistant gas reacting with the cleaning gas to a side surface of the substrate mounting table; an exhaust system configured to be capable of exhausting an atmosphere in the process chamber; and a controller configured to be capable of controlling the process gas supply system, the cleaning gas supply system, and the exhaust system such that the process gas is supplied to the process chamber while the substrate is on the substrate mounting surface and such that the cleaning gas and the cleaning assistant gas are supplied to the side surface of the substrate mounting table while the substrate is not on the substrate mounting surface.

### BRIEF DESCRIPTION OF DRAWINGS

The accompanying drawings, which are incorporated in and constitute a part of the specification, illustrate embodiments of the present disclosure.

FIG. 1 is a diagram illustrating a schematic configuration of a substrate processing apparatus according to embodiments of the present disclosure.

FIG. 2 is an explanatory diagram illustrating a gas supply system of a substrate processing apparatus according to embodiments of the present disclosure.

FIG. 3 is an explanatory diagram illustrating a gas supply system of a substrate processing apparatus according to embodiments of the present disclosure.

FIG. 4 is an explanatory diagram illustrating a controller of a substrate processing apparatus according to embodiments of the present disclosure.

FIG. 5 is a flowchart illustrating a substrate processing process according to embodiments of the present disclosure.

FIG. 6 is a flowchart illustrating details of a substrate processing process according to embodiments of the present disclosure.

FIG. 7 is a flowchart illustrating details of a cleaning step according to embodiments of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail not to obscure aspects of the various embodiments.

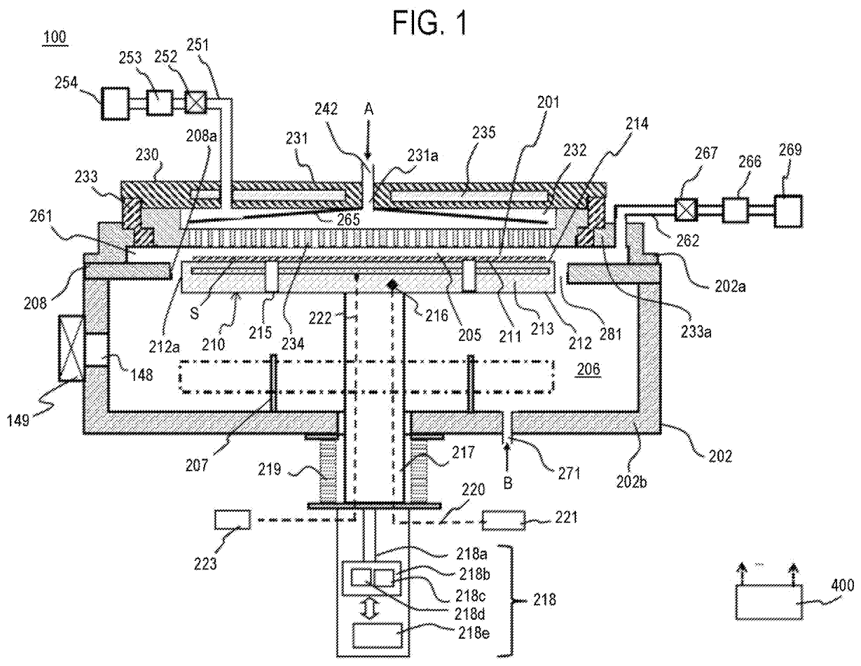

Hereinafter, embodiments of the present disclosure will be described with reference to the accompanying drawings. Hereinafter, aspects of the present disclosure will be described mainly with reference to FIGS. 1 to 7. In addition, the drawings used in the following description are schematic, and dimensional relationships, ratios, and the like among the respective components illustrated in the drawings may not match with actual ones. Further, even among a plurality of drawings, dimensional relationships, ratios, and the like of the respective components may not match one another.

A substrate processing apparatus by way of an example in the following description is used in a process of manufacturing a semiconductor device and is configured to perform a predetermined process processing on a substrate to be processed.

The substrate to be processed is, for example, a silicon wafer (hereinafter simply referred to as “wafer”) as a semiconductor substrate produced by a semiconductor device. In addition, when the word “wafer” is used herein, it may refer to “a wafer itself”, or may refer to “a stack (assembly) of a wafer and a predetermined layer, film or the like formed on a surface thereof” (that is, one including a predetermined layer, film or the like formed on a surface thereof may be called the wafer). Further, when the phrase “a surface of the wafer” is used herein, it may refer to “a surface (exposed surface) of a wafer itself”, or may refer to “a surface of a predetermined layer, film or the like formed on a wafer, that is, an outermost surface of the wafer as a stack”. The word “substrate” as used herein is synonymous with the word “wafer”.

A predetermined process processing performed on the wafer (hereinafter sometimes simply referred to as “processing”) includes, for example, an oxidation processing, a diffusion processing, an annealing processing, an etching processing, a pre-cleaning processing, a chamber cleaning processing, a film-forming processing, and the like. In the embodiments of the present disclosure, specifically, a case of preforming a film-forming processing will be given as an example.

A process temperature herein refers to a temperature of a substrate S or an internal temperature of a process chamber 201, and a process pressure refers to an internal pressure of the process chamber 201. Further, a process time refers to a time during which the processing is continued. These are also applied to the following description.

Embodiments of the present disclosure will be described below with reference to the drawings. However, in the following description, the same reference numerals will be given to the same components, and redundant descriptions thereof may be omitted. In addition, to make the description more clear, the drawings may schematically represent a width, a thickness, a shape, and the like of each component compared to actual aspects, but these are an example and do not limit interpretation of the present disclosure.

(1) Configuration of Substrate Processing Apparatus

FIG. 1 is an explanatory diagram illustrating a substrate processing apparatus according to the embodiments of the present disclosure. Hereinafter, for example, each component of a substrate processing apparatus 100 of FIG. 1 will be specifically described below.

The substrate processing apparatus 100 includes a container 202. The container 202 is configured as, for example, a flat hermetically-sealed container with a circular cross section. Further, the container 202 is made of, for example, metallic material such as aluminum (Al) or stainless steel (SUS). A process space 205 in which the substrate S is processed and a transfer space (or transfer chamber) 206 through which the substrate S passes when the substrate S is transferred to the process space 205 are formed in the container 202. The container 202 includes an upper container 202a and a lower container 202b. A partition plate 208 is installed between the upper container 202a and the lower container 202b. A structure of forming the process space 205 is referred to as a process chamber 201. In the embodiments of the present disclosure, the process chamber 201 mainly includes a distribution plate 234 and a substrate mounting table 212, which will be described later.

A substrate loading/unloading port 148 that is adjacent to a gate valve 149 is installed at a side surface of the lower container 202b. The substrate S moves to and from an adjacent transfer chamber (not illustrated) via the substrate loading/unloading port 148. A plurality of lifting pins 207 are installed at the bottom of the lower container 202b.

A substrate mounting stand 210 on which the substrate S is placed is arranged in the process space 205. The substrate mounting stand 210 includes a substrate mounting surface 211 on which the substrate S is placed, a substrate mounting table 212 including the substrate mounting surface 211 on its surface, and a heater 213 as a heat source installed in the substrate mounting table 212. The heater 213 is arranged below the substrate mounting surface 211.

As a surface provided with the substrate mounting surface 211, an end surface 214 is provided at the outer periphery of the substrate mounting surface 211. During a substrate processing, the substrate S is placed at the substrate mounting surface 211, but no substrate S is placed at the end surface 214.

Through-holes 215, through which the lifting pins 207 pass, are formed in the substrate mounting table 212 at positions corresponding to the lifting pins 207 respectively. The substrate mounting table 212 is made of, for example, quartz.

The substrate mounting table 212 includes therein a temperature gauge 216 as a first temperature gauge configured to measure a temperature of the heater 213. The temperature gauge 216 is connected to a temperature measuring instrument 221 as a first temperature measuring instrument via a wire 220.

A wire 222 configured to supply an electric power is connected to the heater 213. The temperature gauge 216 is connected to a heater controller 223.

The temperature measuring instrument 221 and the heater controller 223 are electrically connected to a controller 400, which will be described later. The controller 400 transmits control information to the heater controller 223 based on temperature information measured by the temperature measuring instrument 221. The heater controller 223 controls the heater 213 by referring to the received control information.

A distribution of heat in the surface of the substrate mounting table 212 is configured such that a temperature of the substrate mounting surface 211 is higher than that of the end surface 214 or a side surface 212a of the substrate mounting table 212. A reason for such a state is considered to be that heat is confined in the substrate mounting surface 211 and escapes from the end surface 214 or the side surface 212a. Specifically, the heat is confined by the substrate S or the like on the substrate mounting surface 211, but the heat may escape from the end surface 214 or the side surface 212a on a side of the substrate mounting table 212.

The substrate mounting table 212 is supported by a shaft 217. The shaft 217 passes through the bottom of the container 202 and is connected to an elevator 218 outside the container 202.

The elevator 218 mainly includes a support shaft 218a configured to support the shaft 217 and an actuator 218b configured to raise or lower or to rotate the support shaft 218a. The actuator 218b includes, for example, a elevating mechanism 218c including a motor configured to perform an elevation and a rotator 218d such as a gear configured to rotate the support shaft 218a.

As a part of the elevator 218, an instructor 218e configured to give an elevation/rotation instruction to the actuator 218b may be installed at the elevator 218. The instructor 218e is electrically connected to the controller 400. The instructor 218e controls the actuator 218b based on an instruction of the controller 400.

By operating the elevator 218 to raise or lower the shaft 217 and the substrate mounting table 212, the substrate mounting table 212 is capable of raising or lowering the substrate S placed on the mounting surface 211. In addition, the periphery of a lower end of the shaft 217 is covered by a bellows 219, whereby the interior of the process space 205 is kept airtight.

When the substrate S is transferred, the substrate mounting table 212 is lowered to a substrate transfer position where the substrate mounting surface 211 faces the substrate loading/unloading port 148. When the substrate S is processed, as illustrated in FIG. 1, the substrate S is raised up to a substrate process position in the process space 205. The substrate process position is also referred to as a first position, and the substrate transfer position is also referred to as a second position.

Once the substrate mounting table 212 is raised to the substrate process position, a cleaning gas flow path 281 is formed between the side surface 212a of the substrate mounting table 212 and a side surface 208a of the partition plate 208. The cleaning gas flow path 281 will be described later.

A shower head (also referred to as SH) 230 as a gas distributor is installed at the top (upstream side) of the process space 205. A through-hole 231a is formed in a lid 231 of the shower head 230. The through-hole 231a is in fluid communication with a common gas supply pipe 242, which will be described later. A buffer space 232 is formed in the shower head 230.

A shower head exhaust pipe 251 is connected to the shower head 230 such that the shower head exhaust pipe 251 is in fluid communication with the buffer space 232. Further, a shower head heater 235 is installed at the shower head 230. In addition, in the embodiments of the present disclosure, the heater 213 may be referred to as a first heater, and the shower head heater 235 may be referred to as a second heater.

A gas guide plate 265 is installed in the buffer space 232. The gas guide plate 265 is formed in a conical shape with a diameter increasing in a radial direction of the substrate S about a gas inlet 241. A lower end of an edge of the gas guide plate 265 is configured to be located on the outer periphery of an end of the substrate S. The gas guide plate 265 is configured to efficiently move the supplied gas toward the distribution plate 234.

The upper container 202a includes a flange, and a support block 233 is placed and fixed on the flange. The support block 233 includes a flange 233a, and the distribution plate 234 is placed and fixed on the flange 233a. Furthermore, the lid 231 is fixed to an upper surface of the support block 233.

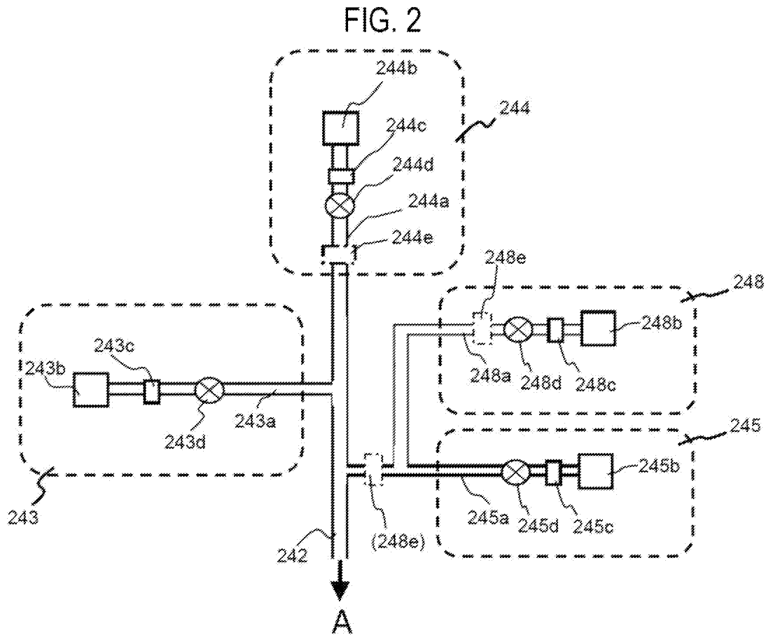

Next, a gas supply system will be described with reference to FIG. 2.

A first gas supply pipe 243a, a second gas supply pipe 244a, a third gas supply pipe 245a, and a fourth gas supply pipe 248a are connected to the common gas supply pipe 242.

At the first gas supply pipe 243a, a first gas source 243b, a mass flow controller (MFC) 243c serving as a flow rate controller (flow rate control part), and a valve 243d serving as an on-off valve are installed sequentially from the upstream side.

The first gas source 243b is a source of a first gas containing a first element (also referred to as a “first element-containing gas”). The first element-containing gas is a precursor gas, that is, a process gas. Here, the first element is, for example, silicon (Si). That is, the first element-containing gas is, for example, a silicon-containing gas. Specifically, a dichlorosilane (SiH₂Cl₂, abbreviation: DCS) gas, a tetraethoxysilane (Si(OC₂H₅)₄, abbreviation: TEOS) gas, or the like is used. In the following description, an example in which the DCS gas is used as the first element-containing gas will be described.

A first gas supply system 243 (also referred to as a silicon-containing gas supply system) mainly includes the first gas supply pipe 243a, the MFC 243c, and the valve 243d. The first gas supply system may also include the first gas source 243b.

At the second gas supply pipe 244a, a second gas source 244b, a MFC 244c, and a valve 244d are installed sequentially from the upstream side.

The second gas source 244b is a source of a second gas containing a second element (also referred to as a “second element-containing gas”). The second element-containing gas is a process gas. In addition, the second element-containing gas may be considered as a reaction gas or modifying gas.

Here, the second element-containing gas contains the second element different from the first element. The second element is any one of oxygen (O), nitrogen (N), and carbon (C), for example. In the embodiments of the present disclosure, the second element-containing gas is, for example, a nitrogen-containing gas, and an example in which ammonia (NH 3) gas is used as the second element-containing gas will be described.

When the substrate S is processed with the second gas in a plasma state, a remote plasma unit 244e may be installed as a plasma generator at the second gas supply pipe.

A second gas supply system 244 (also referred to as a reaction gas supply system) mainly includes the second gas supply pipe 244a, the MFC 244c, and the valve 244d. The second gas supply system 244 may also include a plasma generator. Furthermore, the second gas supply system may also include the second gas source 244b.

At the third gas supply pipe 245a, a third gas source 245b, a MFC 245c, and a valve 245d are installed sequentially from the upstream side.

The third gas source 245b is an inert gas source. An inert gas is, for example, a nitrogen (N₂) gas.

A third gas supply system 245 mainly includes the third gas supply pipe 245a, the MFC 245c, and the valve 245d. The third gas supply system may also include the third gas source 245b.

The inert gas supplied from the inert gas source 245b acts as a purge gas that purges a gas remaining in the container 202 or the shower head 230 in a substrate processing process. Further, in a cleaning process, the inert gas is used as a carrier gas or a diluent gas for a cleaning gas as needed. In this case, the inert gas is supplied into the shower head 230 via the MFC 245c, the valve 245d, and the common gas supply pipe 242.

At the fourth gas supply pipe 248a, a fourth gas source 248b, a MFC 248c, and a valve 248d are installed sequentially from the upstream side. A remote plasma unit 248e may be installed when the cleaning gas is in a plasma state.

When the inert gas is supplied from the third gas supply system 245 during the supply of the cleaning gas, the remote plasma unit 248e may be installed downstream of a confluence of the third gas supply pipe 245a and the fourth gas supply pipe 248a. In doing so, the inert gas collides with the cleaning gas in a plasma state, which may prevent deactivation of the cleaning gas.

The fourth gas source 248b is a cleaning gas source. The cleaning gas is, for example, a NF₃ or F₂ gas. The cleaning gas (fourth gas) supplied from the fourth gas source 248b acts as a cleaning gas that removes by-products and the like adhering to the shower head 230 or the process container 202 in the cleaning process. Specifically, it may be considered to use, for example, a nitrogen trifluoride (NF₃) gas as the cleaning gas. Further, for example, a hydrogen fluoride (HF) gas, a chlorine trifluoride (ClF₃) gas, a fluorine (F₂) gas or the like may be used, or these may be used in combination. In addition, the cleaning gas may also be referred to as an F-containing gas since it contains an F component. One or more selected from these gases may be used as the cleaning gas.

A fourth gas supply system 248 mainly includes the fourth gas supply pipe 248a, the MFC 248c, and the valve 248d. The fourth gas supply system 248 may also include the remote plasma unit 248e. Furthermore, the fourth gas supply system may also include the fourth gas source 248b.

The cleaning gas supplied from the fourth gas source 248b is supplied when cleaning the interior of the process chamber 201 or the shower head 230.

In FIG. 2, an example of a configuration in which each of the first gas supply system 243, the second gas supply system 244, the third gas supply system 245, and the fourth gas supply system 248 is in fluid communication with the process chamber 201 via a common gas supply pipe (first supply pipe 242) is described, but the present disclosure is not limited thereto. For example, the gas supply pipe in each of the first gas supply system 243, the second gas supply system 244, the third gas supply system 245, and the fourth gas supply system 248 may be directly connected to the shower head 230 or the like.

In addition, each of the first gas supply system 243, the second gas supply system 244, and the third gas supply system 245, or a combination thereof may be referred to as a “process gas supply system.” In that case, the process gas supply system performs a function of supplying the process gas or the purge gas to the shower head 230, the process chamber 201 or the like.

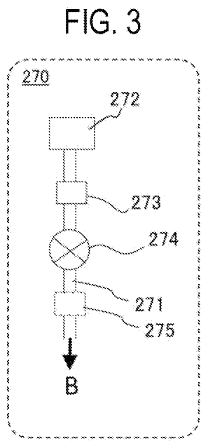

A fifth gas supply pipe 271 is configured to be in fluid communication with the lower container 202b. As illustrated in FIG. 3, at the fifth gas supply pipe 271, a fifth gas source 272, a MFC 273, and a valve 274 are installed sequentially from the upstream side. The fifth gas supply system 270 may also include a remote plasma unit 275.

The fifth gas source 272 is a second cleaning gas source. The second cleaning gas source 272 stores a second cleaning gas different from a first cleaning gas. In the embodiments of the present disclosure, a cleaning assistant gas is stored as the second cleaning gas. The cleaning assistant gas is a gas with characteristics of assisting activation of the first cleaning gas. Specifically, the cleaning assistant gas may be, for example, an oxygen-containing gas such as a NO gas, O₂ gas, H₂O gas, and alcohol. One or more selected from the group of these gases may be used as the cleaning assistant gas.

The fifth gas supply system 270 mainly includes the fifth gas supply pipe 271, the MFC 273, and the valve 274. The fifth gas supply system 270 may also include a fifth gas source 272. Furthermore, the fifth gas supply system 270 may also include a remote plasma unit 275.

The fourth gas supply system 248 is also referred to as a first cleaning gas supply system. The fifth gas supply system 270 is also referred to as a second cleaning gas supply system. Further, a gas supplied from the first cleaning gas supply system is also referred to as the first cleaning gas, and a gas supplied from the second cleaning gas supply system is also referred to as the second cleaning gas. Furthermore, a combination of the first cleaning gas supply system and the second cleaning gas supply system is also referred to as a cleaning gas supply system.

The process space 205 is in fluid communication with an exhaust pipe 262 via an exhaust buffer structure 261. The exhaust buffer structure 261 is installed on the circumference to surround the outer periphery of the substrate S. In the embodiments of the present disclosure, the exhaust buffer structure 261 is arranged between the partition plate 208 and the upper container 202a. The lower surface side of the exhaust buffer structure 261 is configured to be at the same height as the substrate mounting surface 211 in the substrate process position. Accordingly, the cleaning gas flow path 281 is arranged below a lower surface of the exhaust buffer structure 261.

The exhaust pipe 262 is connected to the upper container 202a as the upper side of the exhaust buffer structure 261 such that the exhaust pipe 262 is in fluid communication with the process space 205 via the exhaust buffer structure 261. An auto pressure controller (APC) 266, which is a pressure controller configured to control the interior of the process space 205 at a predetermined pressure, is installed at the exhaust pipe 262. The APC 266 includes a valve (not illustrated) capable of regulating an opening state thereof, and regulates a conductance of the exhaust pipe 262 according to an instruction from the controller 400.

A valve 267 is installed at the upstream side of the APC 266 in the exhaust pipe 262. The exhaust pipe 262, the valve 267, and the APC 266 are collectively referred to as a process chamber exhaust system. Furthermore, a dry pump (DP) 269 is installed at the downstream side of the exhaust pipe 262. The DP 269 exhausts the atmosphere of the process space 205 via the exhaust pipe 262. The process chamber exhaust system may include the DP 269.

The exhaust pipe 251 is connected to the shower head 230 such that the exhaust pipe 251 is in fluid communication with the buffer space 232. For example, the exhaust pipe 251 is connected to a ceiling 231. An auto pressure controller (APC) 253, which is a pressure controller configured to control the buffer space 232 at a predetermined pressure, is installed at the exhaust pipe 251. The APC 253 includes a valve (not illustrated) capable of regulating an opening degree thereof, and regulates the conductance of the exhaust pipe 251 according to an instruction from the controller 400.

A valve 252 is installed at the upstream side of the APC 253 in the exhaust pipe 251. The exhaust pipe 251, the valve 252, and the APC 253 are collectively referred to as a shower head exhaust system. Furthermore, a dry pump (DP) 254 is installed at the downstream side of the shower head exhaust pipe 251. The DP 254 exhausts the atmosphere of the buffer space 232 via the exhaust pipe 251. The shower head exhaust system may include the DP 254. Further, the process chamber exhaust system and the shower head exhaust system may be collectively referred to as an exhaust system.

The substrate processing apparatus 100 includes the controller 400 configured to control an operation of each component of the substrate processing apparatus 100.

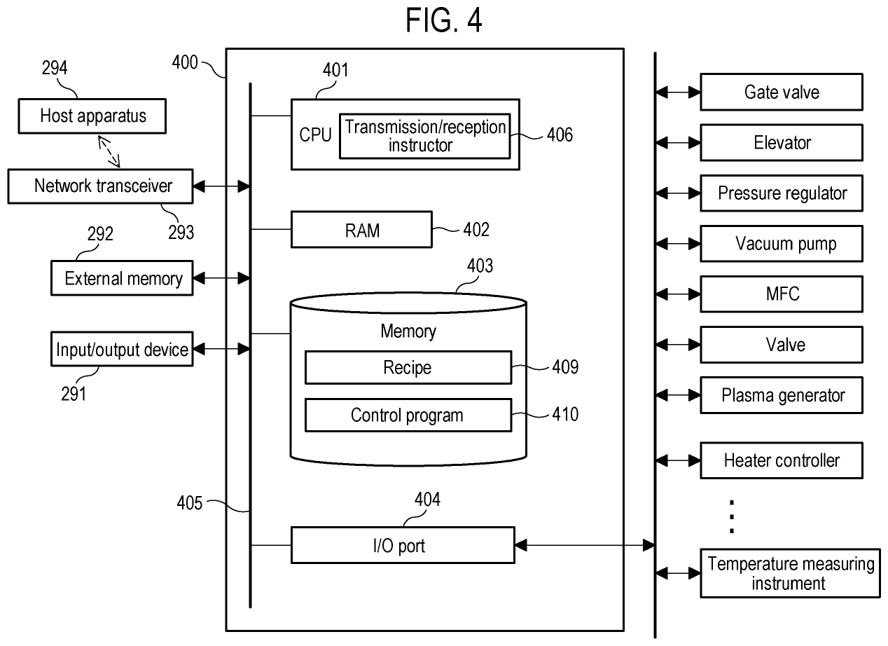

The controller 400 is schematically illustrated in FIG. 4. The controller 400 is configured as a computer including a central processing unit (CPU) 401, a random access memory (RAM) 402, a storage 403 as a storage, and an I/O port 404. The RAM 402, the storage 403, and the I/O port 404 are configured to be capable of exchanging data with the CPU 401 via an internal bus 405. Data transmission/reception in the substrate processing apparatus 100 is performed by an instruction from a transmission/reception instructor 406, which is also a function of the CPU 401.

There is installed a network transceiver 293 that is connected to a host apparatus 294 via a network. The network transceiver 293 is capable of receiving information such as a process history or a process schedule of the substrate S in a lot.

The storage 403 includes, for example, a flash memory, a hard disk drive (HDD), and the like. A process recipe 409 in which procedures, conditions, and the like of a substrate processing are described and a control program 410 that controls the operation of the substrate processing apparatus are readably stored in the storage 403.

In addition, the process recipe is a combination that enables the controller 400 to execute each procedure in a substrate processing process, which will be described later, to obtain a predetermined result, and functions as a program. Hereinafter, this process recipe, control program, and the like will be collectively referred to simply as a program. In addition, when the word “program” is used herein, it may include the process recipe alone, may include the control program alone, or may include both. Further, the RAM 402 is configured as a memory area (work area) in which programs, data, and the like read by the CPU 401 are temporarily held.

The I/O port 404 is connected to each component of the substrate processing apparatus 100 such as the gate valve 149, the elevator 218, each pressure regulator, each pump, and the heater controller 223.

The CPU 401 is configured to read and execute the control program from the storage 403 and to read the process recipe from the storage 403 according to the input of an operation command from an input/output device 291, or the like. Then, the CPU 401 is configured to be capable of controlling the opening/closing operation of the gate valve 149, the elevating operation of the elevator 218, the temperature measuring instrument 221, the heater controller 223, the On/Off control of each pump, the flow rate regulation operation of the MFC, the valve, and the like, according to contents of the read process recipe.

In addition, the controller 400 may configure the controller 400 according to the present disclosure by, for example, installing a program to a computer by using an external storage (for example, a magnetic disk such as a hard disk, an optical disc such as a DVD, a magneto-optical disc such as a MO, and a semiconductor memory such as a USB memory) 292 storing the above-described program. In addition, a configuration in which the program is supplied to the computer is not limited to the supply of the program via the external storage 292. For example, the program may be supplied by using the Internet, a dedicated line or the like without the external storage 292. In addition, the storage 403 and the external storage 292 are configured as a computer-readable recording medium. Hereinafter, these are collectively referred to simply as a recording medium. In addition, when the word “recording medium” is used herein, it may include the storage 403 alone, or may include the external storage 292 alone, or may include both.

(2) Substrate Processing Process

Next, a substrate processing process of processing the substrate S by using the substrate processing apparatus 100 with the above-described configuration will be described as a process of a semiconductor manufacturing process.

Here, a case of forming a thin film on the substrate S will be taken as an example of the substrate processing process. In particular, in the embodiments of the present disclosure, an example in which a DCS gas is used as the precursor gas (first gas), a NH 3 gas is used as the reaction gas (second process gas), and a silicon nitride (SiN) film is formed as a silicon-containing film on the substrate S by alternately supplying those gases will be described.

In addition, in the following description, the operation of each component constituting the substrate processing apparatus 100 is controlled by the controller 400.

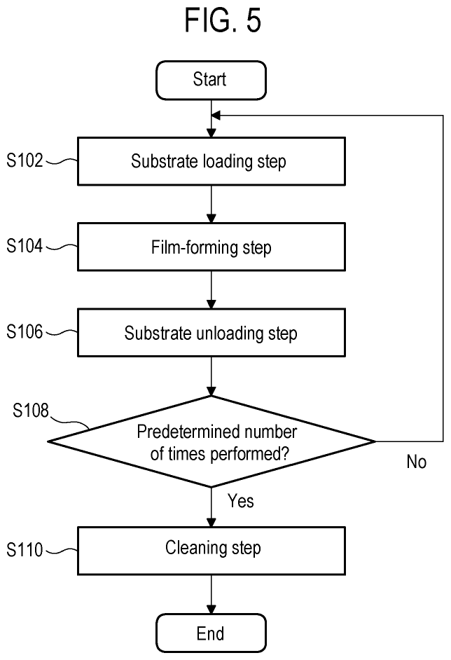

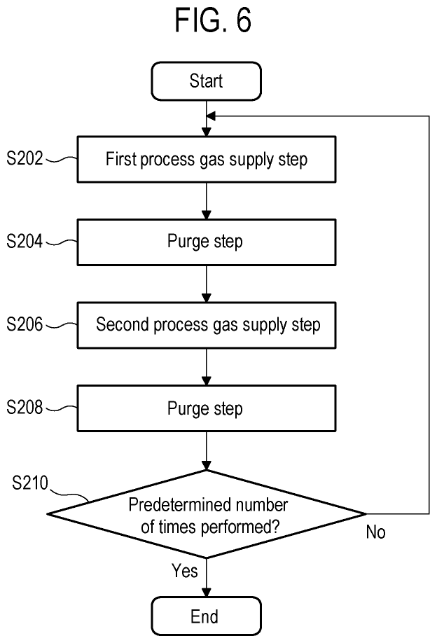

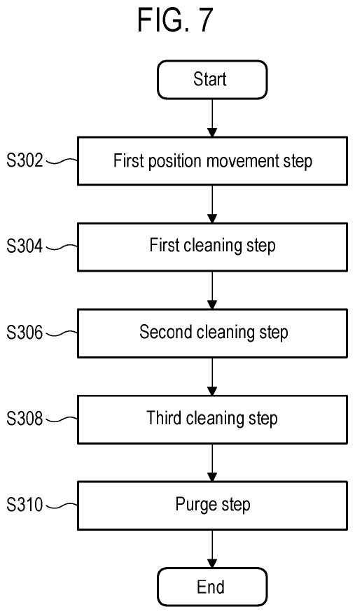

FIG. 5 is a flowchart illustrating the procedure of the substrate processing process according to the embodiments of the present disclosure. FIG. 6 is a flowchart illustrating details of a film-forming step in FIG. 5. FIG. 7 is a flowchart illustrating details of a cleaning step in FIG. 5.

(Substrate Loading Step: S102)

The substrate processing apparatus 100 first performs a substrate loading step S102 in a substrate processing process. In substrate loading step S102, the substrate S is loaded into the process container 202 while the substrate mounting table 212 is at a substrate transfer position (the dotted line in FIG. 1). Then, once the substrate S is loaded into the process container 202, a vacuum transfer robot (not illustrated) is withdrawn out of the process container 202, and the gate valve 149 is closed to hermetically seal the interior of the process container 202. Thereafter, the substrate mounting table 212 is raised to place the substrate S on the substrate mounting surface 211 installed at the substrate mounting table 212. Furthermore, the substrate S is raised to a substrate process position in the process chamber 201 by raising the substrate mounting table 212 to the substrate process position.

After the substrate S is loaded into the transfer space 203, when the substrate S is raised to the substrate process position in the process chamber 201, the APC 266 is operated such that the exhaust buffer chamber 261, the APC 266, and the vacuum pump 269 are in fluid communication. The APC 266 regulates the conductance of the exhaust pipe 262, thereby controlling the exhaust flow rate of the exhaust buffer chamber 261 by the vacuum pump 269 and maintaining the process chamber 201 being in fluid communication with the exhaust buffer chamber 261 at a predetermined pressure.

Further, when placing the substrate S on the substrate mounting table 212, a surface of the substrate S is controlled to become a predetermined process temperature by supplying an electric power to the heater 213 embedded inside the substrate mounting table 212. At this time, the temperature of the heater 213 is regulated by controlling a state of supplying the electrical power to the heater 213 based on temperature information detected by the temperature gauge 216.

In this way, in substrate loading step S102, the interior of the process chamber 201 is controlled to be at a predetermined process pressure, and the surface temperature of the substrate S is controlled to be a predetermined process temperature. Here, the predetermined process temperature and process pressure are the process temperature and process pressure at which a SiN film may be formed by a cyclic processing in film-forming step S104, which will be described later. That is, the process temperature and process pressure are set such that a precursor gas supplied in a first process gas (precursor gas) supply step S202 is not self-decomposed. Specifically, the process temperature may be room temperature or higher and 500 degrees C. or lower, particularly room temperature or higher and 400 degrees C. or lower, and the process pressure may be 50 Pa to 5000 Pa. The process temperature and the process pressure are also maintained in a film-forming step S104, which will be described later.

(Film-Forming Step: S104)

After substrate loading step S102, subsequently, a film-forming step S104 is performed. Hereinafter, the film-forming step S104 will be described in detail with reference to FIG. 6. In addition, the film-forming step S104 is a cyclic processing in which different process gases are alternately supplied.

(First Process Gas Supply Step: S202)

In film-forming step S104, first, a first process gas (precursor gas) supply step S202 is performed in a state where the substrate S is present. In the first process gas supply step S202, a DCS gas is supplied as the precursor gas (first gas) into the process chamber 201 from the first gas supply system 243. The DCS gas supplied into the process chamber 201 reaches above the surface of the substrate S at the substrate process position. Thus, the DCS gas comes into contact with the surface of the substrate S, such that a silicon-containing layer as a “first element-containing layer” is formed on the surface. The silicon-containing layer is formed with a predetermined thickness and a predetermined distribution according to, for example, an internal pressure of the process container 202, a flow rate of the DCS gas, a temperature of the substrate mounting table 212, a time taken to pass through the process chamber 201, and the like.

When a predetermined time elapses after the supply of the DCS gas is started, the valve 243d is closed to stop the supply of the DCS gas. In addition, in the first process gas supply step S202, the internal pressure of the process chamber 201 is controlled to a predetermined pressure by the APC 266.

(Purge Step: S204)

After the first process gas supply step S202, subsequently, a N₂ gas is supplied from the third gas supply system 245, and an atmosphere purge in the process chamber 201 and the shower head 230 is performed. Thus, the DCS gas that cannot be bonded to the substrate S in the first process gas supply step S202 is removed from the process chamber 201 by the vacuum pump 269.

(Second Process Gas Supply Step: S206)

After the purge step S204, subsequently, a NH 3 gas is supplied as the reaction gas (second gas) into the process chamber 201 from the reaction gas supply system 244. The NH 3 gas may be turned into a plasma state by the RPU 244e and may be emitted to the surface of the substrate S at the substrate process position. Thus, the already formed silicon-containing layer is modified on the surface of the substrate S to form a SiN film, which is, for example, a layer containing a Si element and a N element.

Then, after a predetermined time elapses, the valve 244d is closed to stop the supply of the NH 3 gas. In addition, in second process gas supply step S206, the pressure of the process chamber 201 is controlled to be a predetermined pressure by the APC 266, as in the above-described first process gas supply step S202.

(Purge Step: S208)

After second process gas supply step S206, a purge step S208 is performed. The operation of each component in purge step S208 is the same as in a case of the above-described purge step S204, and therefore, the description thereof is omitted here.

(Determination Step: S210)

Upon completion of the purge step S208, the controller 400 continuously determines, with the above-described series of steps S202 to S208 being set as a cycle, whether or not the cycle is performed a predetermined number of times (n cycles). Then, in a case where the cycle is not been performed the predetermined number of times, the controller 400 performs, one or more times, the cycle from the first process gas supply step S202 to the purge step S208. On the other hand, when the cycle is performed the predetermined number of times, the controller 400 completes the film-forming step S104.

As described above, in the film-forming step S104, a SiN film with a predetermined thickness is deposited on the surface of the substrate S by sequentially performing each process from the first process gas supply step S202 to the purge step S208. Then, the SiN film formed on the surface of the substrate S is controlled to a desired film thickness by setting the respective steps as a cycle and performing the cycle a predetermined number of times.

(Substrate Unloading Step: S106)

After completion of the film-forming step S104 as described above, the substrate processing apparatus 100 performs a substrate unloading step S106, as illustrated in FIG. 2. In the substrate unloading step S106, the processed substrate S is unloaded out of the process container 202 in the reverse procedure of the above-described substrate loading step S102. Then, in the same procedure as the substrate loading step S102, a next waiting unprocessed substrate S is loaded into the process container 202. Thereafter, the film-forming step S104 is performed on the loaded substrate S.

(Determination Step: S108)

Upon completion of substrate unloading step S106, the substrate processing apparatus 100 determines, with the above-described series of steps S102 to S106 being set as a cycle, whether or not the cycle is performed a predetermined number of times, that is, whether or not the number of substrates S processed in the film-forming step S104 reaches a predetermined number. Then, since the number of processed substrates S does not reach the predetermined number in a case where the cycle is not performed the predetermined number of times, the cycle from the substrate loading step S102 to the substrate unloading step S106 is performed one or more times. On the other hand, when the cycle is performed the predetermined number of times, the substrate processing process is completed.

When the substrate processing process is completed, the substrate S is not present in the process container 202.

The process gas is supplied to the substrate S and is discharged via an exhaust buffer, but, in the middle of such an operation, may be circulated around the side surface 212a. Therefore, the gas may adhere to the side surface 212a, resulting in by-products.

Over the substrate mounting surface 211, the temperature is regulated such that a controlled dense film is formed on the substrate S. On the other hand, on the side surface 212a or the end surface 214, the temperature control is not performed since there is no need to form a dense film. Therefore, a variation in stress occurs in the uncontrolled film adhering to the side surface 212a. In doing so, the film adhering to the side surface 212a may be peeled off and become particles.

Therefore, after processing a predetermined number of substrates, cleaning step S110 is performed. Further, in this case, it is described that the cleaning step is performed after processing the predetermined number of substrates, but the present disclosure is not limited thereto, and a cleaning step S110 may be performed after a predetermined cumulative process time.

(Cleaning Step S110)

Next, as a step of a substrate processing method or a method of manufacturing a semiconductor device, a cleaning step S110 for the interior of the process container 202 of the substrate processing apparatus 100 will be described in detail.

When the above-described substrate processing process is performed one or more times, in the process container 202 (in particular, in the process chamber 201), reactants such as by-products may potentially adhere to the wall surface of the process container, the end surface 214, and the side surface 212a. Therefore, the substrate processing apparatus 100 performs the cleaning step of the process chamber 201 at a predetermined timing (for example, after performing the substrate processing process a predetermined number of times, after processing a predetermined number of substrates S, after a predetermined time elapses from the previous cleaning processing, or the like).

In the cleaning step S110, the cleaning gas and the cleaning assistant gas are supplied without the substrate S on the substrate mounting table 212, and deposits (reaction by-products, etc.) adhering to at least one selected from the group of the interior of the buffer space 232 or the process chamber 201, and the end surface 214 and the side surface 212a of the substrate mounting table 212, are removed. At this time, a cleaning processing is performed without the substrate in the process chamber 201 and without the process gas.

The cleaning processing is performed, for example, under the following condition:
Internal temperature of process chamber: 200 degrees C. to 600 Degrees C.;
Internal pressure of process chamber: 133 Pa (1 Torr) to 66500 Pa (500 Torr);
NF₃ gas supply flow rate: 200 sccm (0.2 slm) to 4000 sccm (4 slm);
NO gas supply flow rate: 200 sccm (0.2 slm) to 4000 sccm (4 slm);
N₂ gas supply flow rate: 500 sccm (0.5 slm) to 20000 sccm (20 slm).

In addition, notation of a numerical range such as “1 to 2000 Pa” herein means that a lower limit value and an upper limit value thereof are included in that range. Accordingly, for example, “1 to 2000 Pa” means “1 Pa or more and 2000 Pa or less.” The same is also applied to other numerical ranges.

In addition, in a case where the cleaning gas is to be diluted or the carrier gas is to be provided, the valve 245d is opened to supply the inert gas.

Next, a comparative example of the present disclosure will be described. As the comparative example, it is conceivable that the cleaning gas is supplied alone to the process chamber 201 without supplying the cleaning assistant gas. For example, the first cleaning gas supplied from the fourth gas supply system is supplied to the process chamber 201 via the buffer space 232. The cleaning gas supplied to the process chamber 201 cleans the walls and the like constituting the process chamber 201, and is then discharged from the exhaust pipe 262 via the exhaust buffer structure 261.

As a result of investigations by the present discloser, it was found that, in the method of the comparative example, there is a location where cleaning is insufficient at the downstream side of the cleaning gas flow. The location where the cleaning is insufficient is, for example, the end surface 214 or the side surface 212a. Next, the reason that the cleaning becomes insufficient will be described. The cleaning gas reaches the end surface 214 or the side surface 212a via the buffer space 232 and the process chamber 201. The cleaning gas becomes deactivated before reaching the end surface 214 or the side surface 212a because it performs the cleaning processing in the buffer space 232 or the process chamber 201. Therefore, an energy of the cleaning gas becomes insufficient at the end surface 214 or the side surface 212a.

In particular, since the cleaning gas is discharged via the exhaust buffer structure 261, a portion of the cleaning gas reaches the side surface 212a, but most of the cleaning gas may flow toward the exhaust buffer structure 261. That is, an amount of cleaning gas may be less sufficient on the side surface 212a.

With respect to these concerns, the present disclosure describes a method of sufficiently cleaning the end surface 214 or the side surface 212a. Detail description will follow.

(First Position Movement Step S302)

Next, a first position movement step S302 will be described. The substrate mounting table 212 is moved to a first position without the substrate on the substrate mounting table 212. In doing so, the cleaning gas flow path 281 is formed between the side surface 212a and the side surface 208a. At this time, the heater 213 is set such that a temperature of the side surface 212a, that is, a temperature of the cleaning gas flow path is set to a temperature at which the cleaning gas and the cleaning assistant gas may react to enable the cleaning process. In addition, due to the configuration of the substrate mounting table 212, as described above, the temperature of the cleaning gas flow path is lower than the temperature of the process chamber 201.

(First Cleaning Step S304)

Next, a first cleaning step S304 will be described. When the substrate mounting table 212 is moved to the first position, the cleaning gas is supplied from the first cleaning gas supply system 248 while the heater 213 is in operation. Further, the valve 267 is opened and the valve 252 is closed. Since the heater 213 is in operation, the temperature of the cleaning gas flow path is lower than the temperature of the process chamber 201.

The cleaning gas is supplied to the process chamber 201 via the shower head 230. In addition, although in the present disclosure, it is described that the valve 267 is opened and the valve 252 is closed, other operations may be performed as long as the cleaning gas and the cleaning assistant gas may be discharged from the exhaust buffer structure 261, and for example, opening states of the valves and the like may be regulated such that an exhaust amount of the process chamber exhaust system is greater than an exhaust amount of the shower head exhaust system.

More specifically, the cleaning assistant gas is controlled not to hinder the cleaning gas from diffusing into the process chamber 201 or into the cleaning gas flow path 281. For example, the valve 248d is opened to supply the cleaning gas into the process chamber 201 or into the cleaning gas flow path, and the valve 274 is closed not to supply the cleaning assistant gas into the process chamber 201 or into the cleaning gas flow path 281.

In doing so, it is possible to prevent the cleaning assistant gas from hindering the diffusion of the cleaning gas. Accordingly, the cleaning gas may be diffused into the process chamber 201, and the cleaning gas may be supplied to the interior of the process chamber 201, the end surface 214, and the side surface 212a. In a case where the cleaning assistant gas is supplied into the process chamber 201 or the cleaning gas flow path 281 before the cleaning gas is supplied, the diffusion of the cleaning gas to the end surface 214 or the side surface 212a may become insufficient, resulting in an insufficient cleaning process.

(Second Cleaning Step S306)

A second cleaning step S306 will be described.

When a predetermined time elapses after the supply of the cleaning gas is started, the cleaning assistant gas is supplied from the second cleaning gas supply system 270. At this time, the first cleaning step S304 is followed by the supply of the cleaning gas and the discharge of the cleaning gas from the process chamber exhaust system. Furthermore, the operation of the heater 213 is maintained. Therefore, the temperature of the cleaning gas flow path is kept lower than the temperature of the process chamber 201.

The cleaning assistant gas is supplied to the cleaning gas flow path 281 via the transfer space 206. At this time, in the cleaning gas flow path 281, the cleaning gas and the cleaning assistant gas merge and react with each other to activate the cleaning gas. Thus, it may clean the side surface 212a. The merged cleaning gas and cleaning assistant gas are discharged from the exhaust buffer structure 261.

In addition, the predetermined time in the present step indicates a time during which the cleaning gas and the cleaning assistant gas may merge with each other in the cleaning gas flow path 281. For example, the predetermined time indicates a time taken for at least the cleaning gas to reach the cleaning gas flow path 281. By delaying the supply of the cleaning assistant gas for the predetermined time, the cleaning gas and the cleaning assistant gas merge into the cleaning gas flow path 281.

At this time, the process chamber exhaust system, the first cleaning gas supply system, and the second cleaning gas supply system are controlled to cooperate with one another such that the cleaning gas and the cleaning assistant gas may merge in the cleaning gas flow path 281.

In the cleaning gas flow path 281, the deactivated cleaning gas is activated by the cleaning assistant gas to clean the side surface 212a.

In addition, in a case where the cleaning assistant gas is supplied without waiting for the lapse of the predetermined time, the cleaning gas flow path 281 is filled with the cleaning assistant gas. In doing so, a pressure of the cleaning gas flow path 281 becomes high, creating an environment in which it is difficult for the cleaning gas to be supplied to the cleaning gas flow path 281, which may cause insufficient cleaning of the side surface 212a. In contrast, by supplying the cleaning assistant gas after the predetermined time elapses as described above, the cleaning gas may be supplied to the cleaning gas flow path, and thus may sufficiently clean the side surface 212a.

(Third Cleaning Step: S308)

Next, a third step S308 will be described.

Here, when a predetermined time elapses after the supply of the cleaning gas is started in the second step S306, the cleaning assistant gas is supplied from the second cleaning gas supply system in a state where the first cleaning gas supply system continues to supply the cleaning gas. Further, the valve 267 is closed, the valve 252 is opened, and the operation of the heater 213 is maintained. The temperature of the cleaning gas flow path is kept lower than the temperature of the process chamber 201.

In doing so, the cleaning assistant gas is discharged from the shower head exhaust system via the transfer chamber 206, the cleaning gas flow path 281, and the end surface 214. The deactivated cleaning gas and the cleaning assistant gas merge and react with each other over the end surface 214, and the deactivated cleaning gas is activated by the cleaning assistant gas to perform a cleaning over the end surface 214.

In addition, in this step, after the cleaning gas and the cleaning assistant gas merge over the end surface 214, a supply amount of the cleaning gas may be smaller than that in the second cleaning step. For example, the supply of the cleaning gas may be stopped. In doing so, the remaining cleaning gas reacts with the cleaning assistant gas over the end surface 214 to perform the cleaning over the end surface 214. On the other hand, since no new cleaning gas is replenished for the substrate mounting surface 211 or the distribution plate 234, it is possible to prevent the merging of the cleaning gas and the cleaning assistant gas. In a case where the cleaning gas and the cleaning assistant gas merge at the substrate mounting surface 211, distribution holes of the distribution plate 234, the distribution plate 270, or the like, the cleaning gas may be further activated, causing the substrate mounting surface 211, the distribution plate 234, or the distribution plate 270 to be etched.

In particular, since the substrate is placed on the substrate mounting surface 211 in the film-forming step S104, an amount of cleaning objects is small over the substrate mounting surface 211, and thus, the substrate mounting surface 211 is easily etched when it comes into contact with the high-energy cleaning gas.

In particular, when the substrate mounting stand 210 is made of heat-transmitting material such as quartz, the substrate mounting surface 211 is etched, causing a diffuse reflection of heat from the heater 213, which may lead to uneven heating of the substrate S. In the present disclosure, since etching may be prevented, uneven heating may be prevented even when the substrate mounting stand 210 is made of the heat-transmitting material.

Furthermore, the inert gas may be supplied from the third gas supply system. In doing so, a residual gas of the cleaning gas may be purged from the vicinity of the substrate mounting surface 211, the distribution holes of the distribution plate 234, and the distribution plate 270. This may further prevent etching.

In addition, although it is described here that the valve 252 is opened and the valve 267 is closed, other operations may be performed as long as the cleaning gas and the cleaning assistant gas which contributed to the cleaning of the end surface 214 may be discharged from the shower head exhaust system. For example, opening states of the valves and the like may be regulated such that an exhaust amount of the shower head exhaust system is greater than an exhaust amount of the process chamber exhaust system.

(Purge Step S310)

Upon completion of third cleaning step S308, while the valve 252 is opened, the inert gas is supplied from the third gas supply system, and the cleaning gas and cleaning assistant gas are removed from the process chamber 201 and the buffer space 232. At this time, the valve 267 may be opened.

In addition, it is described in the aforementioned embodiments of the present disclosure that a combination from the first cleaning step S304 to the third cleaning step S308 is performed one time, but the present disclosure is not limited thereto. For example, the combination from the first cleaning step S304 to the third cleaning step S308 may be performed two or more times. In doing so, the cleaning processing is performed by a fresh cleaning gas and a fresh cleaning assistant gas, whereby more precise cleaning is possible.

Further, when the combination from the first cleaning step S304 to the second cleaning step S308 is performed one or more times, purge step S310 may be performed. Thus, it is possible to use the fresh cleaning gas and the fresh cleaning assistant gas, whereby more precise cleaning is possible.

### Other Embodiments

Although the embodiments of the present disclosure are specifically described above, the present disclosure is not limited to the respective embodiments described above, and various modifications may be made without departing from the scope of the present disclosure.

For example, in the above-described embodiments, the cleaning gas is supplied from the fourth gas supply system 248 and the cleaning assistant gas is supplied from the second cleaning gas supply system 270, but the present disclosure is not limited thereto. Other operations may be performed as long as the cleaning gas and the cleaning assistant gas may merge in the cleaning gas flow path 281, and for example, the cleaning assistant gas may be supplied from the fourth gas supply system 248 and the cleaning gas may be supplied from the second cleaning gas supply system 270.

Further, the above-described embodiments of the present disclosure are described by way of the example where, in the substrate processing process, the DCS gas is used as the precursor gas (first gas), the NH₃ gas is used as the reaction gas (second gas), and these gases are alternately supplied to from the SiN film on the wafer, but the present disclosure is not limited thereto. That is, the process gas used in the film-forming process is not limited to the DCS gas, NH₃ gas or the like, and other types of gases may be used to form other types of thin films. Furthermore, the present disclosure may be applied even to a case where three or more types of process gases are used.

Further, the above-described embodiments of the present disclosure are described by way of the example where, when the SiN film, which is a nitride film, is formed on the wafer, the NF₃ gas, F₂ gas or the like is used as the cleaning gas, and the NO gas, O₂ gas or the like is used as the cleaning assistant gas, but the present disclosure is not limited thereto. For example, when an oxide film (for example, a SiO film) is formed on the wafer, hydrogen fluoride (HF) may be used as the cleaning gas, and water (H₂O) or alcohol may be used as the cleaning assistant gas.

The embodiments and modifications described above may be appropriately combined and used. In such a case, processing procedures and processing conditions may be the same as the processing procedures and processing conditions in the above-described embodiments and modifications, for example.

According to the present disclosure in some embodiments, it is possible to reduce an influence of an unintended film formed on a substrate mounting table.

While certain embodiments are described above, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a process chamber configured to be capable of processing a substrate;
a substrate mounting table including a substrate mounting surface on which the substrate is placed;
a process gas supply system configured to supply a process gas into the process chamber;
a cleaning gas supply system configured to supply a cleaning gas and a cleaning assistant gas reacting with the cleaning gas to a side surface of the substrate mounting table;
an exhaust system configured to be capable of exhausting an atmosphere in the process chamber; and
a controller configured to be capable of controlling the process gas supply system, the cleaning gas supply system, and the exhaust system such that the process gas is supplied to the process chamber while the substrate is on the substrate mounting surface and such that the cleaning gas and the cleaning assistant gas are supplied to the side surface of the substrate mounting table while the substrate is not on the substrate mounting surface.

2. The substrate processing apparatus of claim 1, wherein the cleaning gas supply system includes:
a first cleaning gas supply system configured to be capable of supplying the cleaning gas or the cleaning assistant gas to the process chamber; and
a second cleaning gas supply system configured to be capable of supplying a gas different the gas supplied from the first cleaning gas supply system.

3. The substrate processing apparatus of claim 2, wherein a transfer chamber configured to be capable of transferring the substrate is installed below the process chamber, and
wherein the second cleaning gas supply system is further configured to supply the cleaning assistant gas via the transfer chamber.

4. The substrate processing apparatus of claim 1, wherein the cleaning gas supply system is further configured to supply the cleaning gas and the cleaning assistant gas such that the cleaning gas and the cleaning assistant gas are mixed at a side of the substrate mounting table.

5. The substrate processing apparatus of claim 1, wherein the cleaning assistant gas is capable of reacting with the cleaning gas to clean the side surface of the substrate mounting table.

6. The substrate processing apparatus of claim 1, further comprising an elevator configured to be capable of raising or lowering the substrate mounting table,
wherein the controller is further configured to control the elevator to form a cleaning gas flow path at a side of the substrate mounting table.

7. The substrate processing apparatus of claim 6, wherein the cleaning gas supply system includes:
a first cleaning gas supply system configured to be capable of supplying the cleaning gas or the cleaning assistant gas to the process chamber; and
a second cleaning gas supply system configured to be capable of supplying a gas different from the gas supplied from the first cleaning gas supply system,
wherein the gas supplied from the second cleaning gas supply system is supplied to the cleaning gas flow path.

8. The substrate processing apparatus of claim 7, wherein a temperature of the cleaning gas flow path is lower than a temperature of the process chamber when supplying the cleaning assistant gas from the second cleaning gas supply system.

9. The substrate processing apparatus of claim 1, wherein an end surface is formed on a surface of the substrate mounting table provided with the substrate mounting surface, and
wherein the cleaning gas supply system is further configured to cause the cleaning gas and the cleaning assistant gas to react with each other on the end surface.

10. The substrate processing apparatus of claim 1, further comprising a shower head installed at an upstream side of the process chamber,
wherein the cleaning gas supply system includes:
a first cleaning gas supply system configured to be capable of supplying the cleaning gas or the cleaning assistant gas to the process chamber; and
a second cleaning gas supply system configured to be capable of supplying a gas different from the gas supplied from the first cleaning gas supply system to the side surface of the substrate mounting table,
wherein the exhaust system includes a process chamber exhaust system arranged at a side of the process chamber and a shower head exhaust system installed at the shower head, and
wherein the cleaning gas supply system is further configured to supply the cleaning gas and the cleaning assistant gas while an exhaust amount of the process chamber exhaust system is greater than an exhaust amount of the shower head exhaust system.

11. The substrate processing apparatus of claim 1, further comprising a shower head installed at an upstream side of the process chamber,
wherein the cleaning gas supply system includes:
a first cleaning gas supply system configured to be capable of supplying the cleaning gas or the cleaning assistant gas to the process chamber; and
a second cleaning gas supply system configured to be capable of supplying a gas different from the gas supplied from the first cleaning gas supply system to the side surface of the substrate mounting table,
wherein the exhaust system includes a process chamber exhaust system arranged at a side of the process chamber and a shower head exhaust system installed at the shower head, and
wherein the cleaning gas supply system is further configured to supply the cleaning gas and the cleaning assistant gas while an exhaust amount of the shower head exhaust system is greater than an exhaust amount of the process chamber exhaust system.

12. The substrate processing apparatus of claim 1, wherein the cleaning gas supply system is further configured to start supplying the cleaning assistant gas when a predetermined time elapses after the supply of the cleaning gas is started.

13. The substrate processing apparatus of claim 1, wherein the cleaning gas supply system is further configured to start supplying the cleaning assistant gas while the supply of the cleaning gas is maintained.

14. The substrate processing apparatus of claim 1, wherein the cleaning gas supply system is further configured to start supplying the cleaning gas without supplying the cleaning assistant gas to the process chamber.

15. The substrate processing apparatus of claim 1, wherein the controller is further configured to perform a control such that the supply of the cleaning gas and the supply of the cleaning assistant gas are performed at least one or more times.

16. The substrate processing apparatus of claim 1, further comprising a shower head installed at an upstream side of the process chamber,
wherein an inert gas is supplied to the shower head while the cleaning assistant gas is supplied from the cleaning gas supply system.

17. A method of processing a substrate, comprising:
supplying a process gas to a process chamber while the substrate is on a substrate mounting surface of a substrate mounting table arranged in the process chamber; and
supplying a cleaning gas and a cleaning assistant gas to a side surface of the substrate mounting table while the substrate is not on the substrate mounting surface.

18. A method of manufacturing a semiconductor device comprising the method of claim 17.

19. A cleaning method comprising:
supplying a cleaning gas and a cleaning assistant gas to a side surface of a substrate mounting table while a substrate is not on a substrate mounting surface of the substrate mounting table.

20. A non-transitory computer-readable recording medium recording a program that causes, by a computer, a substrate processing apparatus to perform the method of claim 17.
